(19) United States
(12) Patent Application Publication
(10) Pub. No.: US 2025/0218993 A1
(43) Pub. Date: Jul. 3, 2025

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Tian HU, Hsinchu City (TW); Po-Han WANG, Hsinchu City (TW); Yu-Hsiang HU, Hsinchu City (TW); Hung-Jui KUO, Hsinchu City (TW)

(21) Appl. No.: 18/402,935

(22) Filed: Jan. 3, 2024

(51) Int. Cl. H01L 23/00; H01L 21/768; H01L 23/498

(52) U.S. Cl. CPC H01L 24/13; H01L 21/76885; H01L 23/49822; H01L 24/11; H01L 24/32; H01L 24/73; H01L 2224/11002; H01L 2224/13022; H01L 2224/32225; H01L 2224/73204; H01L 2924/13091

(57) ABSTRACT

A method for forming a semiconductor device structure is provided. The method includes providing a substrate, a first insulating layer, and a conductive pillar over the substrate. The conductive pillar is embedded in the first insulating layer, and a top surface of the conductive pillar is exposed by the first insulating layer. The method includes forming a second insulating layer over the first insulating layer and the conductive pillar. The second insulating layer has a hole over the top surface of the conductive pillar. The method includes forming a conductive via structure in the hole and a conductive line over the conductive via structure and the second insulating layer. The conductive via structure has a first strip shape in a first top view of the conductive via structure.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1D are cross-sectional views of various stages of a process for forming a semiconductor device structure, in accordance with some embodiments.

FIG. 1C-1 is a top view of the semiconductor device structure of FIG. 1C, in accordance with some embodiments.

FIG. 1D-1 is a top view of the semiconductor device structure of FIG. 1D, in accordance with some embodiments.

FIGS. 2A-2D are cross-sectional views of various stages of a process for forming a semiconductor device structure, in accordance with some embodiments.

FIG. 2C-1 is a top view of the semiconductor device structure of FIG. 2C, in accordance with some embodiments.

FIG. 2D-1 is a top view of the semiconductor device structure of FIG. 2D, in accordance with some embodiments.

FIGS. 3A-3F are cross-sectional views of various stages of a process for forming a semiconductor device structure, in accordance with some embodiments.

FIG. 3E-1 is a top view of the semiconductor device structure of FIG. 3E, in accordance with some embodiments.

FIG. 3F-1 is a top view of the semiconductor device structure of FIG. 3F, in accordance with some embodiments.

FIGS. 4A-4E are cross-sectional views of various stages of a process for forming a semiconductor device structure, in accordance with some embodiments.

FIG. 4D-1 is a top view of the semiconductor device structure of FIG. 4D, in accordance with some embodiments.

FIG. 4E-1 is a top view of the semiconductor device structure of FIG. 4E, in accordance with some embodiments.

FIGS. 5A-5E are cross-sectional views of various stages of a process for forming a semiconductor device structure, in accordance with some embodiments.

FIG. 5D-1 is a top view of the semiconductor device structure of FIG. 4D, in accordance with some embodiments.

FIG. 5E-1 is a top view of the semiconductor device structure of FIG. 4E, in accordance with some embodiments.

FIG. 6 is a cross-sectional view of a package structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

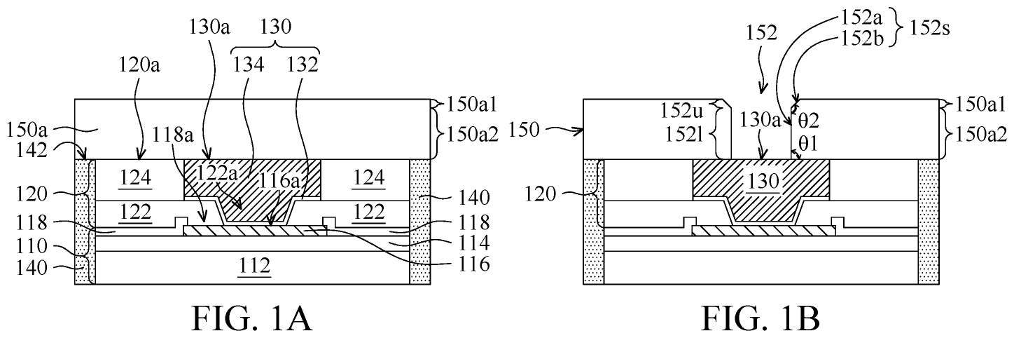

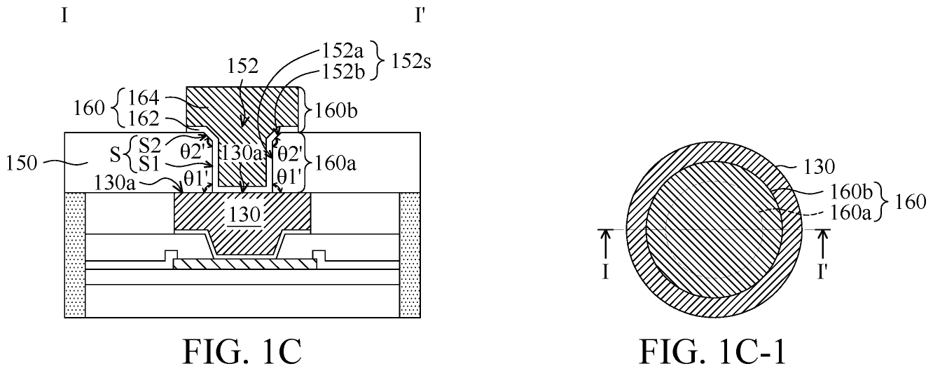

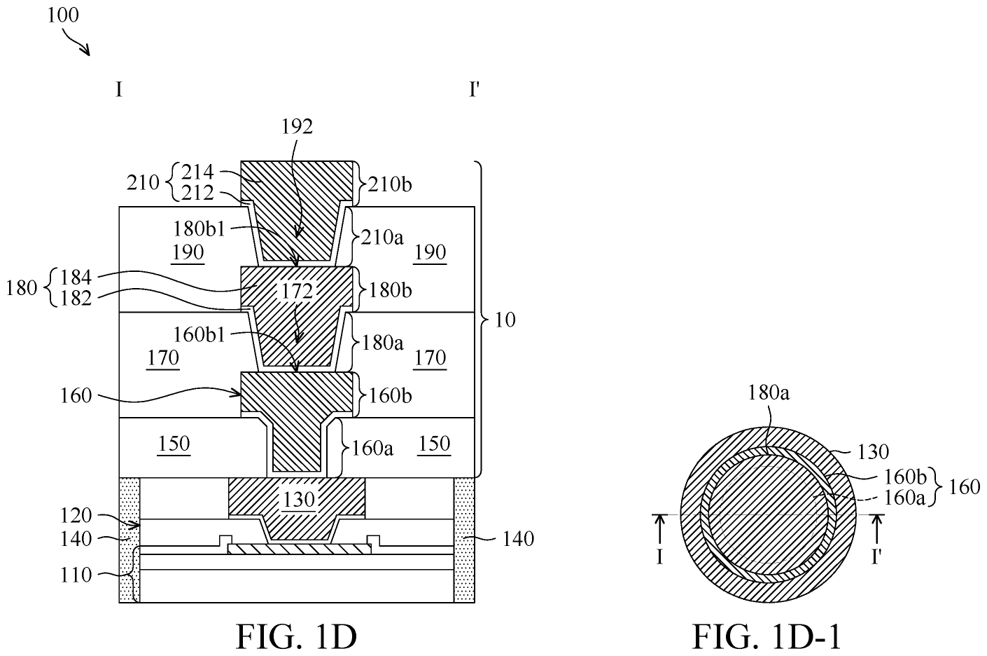

FIGS. 1A-1D are cross-sectional views of various stages of a process for forming a semiconductor device structure, in accordance with some embodiments. As shown in FIG. 1A, a substrate 110, an insulating layer 120, a conductive pillar 130, and a molding layer 140 are provided, in accordance with some embodiments.

The substrate 110 includes a semiconductor substrate 112, devices, an interconnect structure 114, a bonding pad 116, and a passivation layer 118 over the semiconductor substrate 112, in accordance with some embodiments. The devices are not shown in figures for the purpose of simplicity and clarity.

The semiconductor substrate 112 is made of an elementary semiconductor material including silicon or germanium in a single crystal structure, a polycrystal structure, or an amorphous structure. In some other embodiments, the semiconductor substrate 112 is made of a compound semiconductor, such as silicon carbide, gallium arsenide, gallium phosphide, indium phosphide, indium arsenide, an alloy semiconductor, such as SiGe, or GaAsP, or a combination thereof. The semiconductor substrate 112 may also include multi-layer semiconductors, semiconductor on insulator (SOI) (such as silicon on insulator or germanium on insulator), or a combination thereof.

In some embodiments, the devices are formed in and/or over the semiconductor substrate 112. Examples of the various devices include active devices, passive devices, other suitable elements, or a combination thereof. The active devices may include transistors or diodes formed at a surface of the semiconductor substrate 112. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 112. The isolation features are used to define active regions and electrically isolate various devices formed in and/or over the semiconductor substrate 112 in the active regions. In some embodiments, the isolation features include shallow trench isolation (STI) features, local oxidation of silicon (LOCOS) features, other suitable isolation features, or a combination thereof.

The interconnect structure 114 is formed over the devices and the semiconductor substrate 112, in accordance with some embodiments. The interconnect structure 114 includes a dielectric layer, wiring layers, and conductive vias, in accordance with some embodiments. The wiring layers and the conductive vias are in the dielectric layer, in accordance with some embodiments. The conductive vias are electrically connected between the wiring layers and the devices, in accordance with some embodiments.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments. The wiring layers and the conductive vias are made of a conductive material, such as metal (e.g., copper, aluminum, gold, silver, or tungsten) or alloys thereof, in accordance with some embodiments.

The bonding pad 116 is formed over the interconnect structure 114, in accordance with some embodiments. The bonding pad 116 is electrically connected to the wiring layers and the conductive vias of the interconnect structure 114, in accordance with some embodiments. The bonding pad 116 is made of a conductive material, such as metal (e.g., copper, aluminum, gold, silver, or tungsten) or alloys thereof, in accordance with some embodiments.

The passivation layer 118 is over the interconnect structure 114 and the bonding pad 116, in accordance with some embodiments. The passivation layer 118 has an opening 118a, in accordance with some embodiments. The opening 118a exposes a top surface 116a of the bonding pad 116, in accordance with some embodiments. The passivation layer 118 is made of a dielectric material such as a nitride-containing material (e.g., silicon nitride), in accordance with some embodiments.

The insulating layer 120 and the conductive pillar 130 are formed over the substrate 110, in accordance with some embodiments. The conductive pillar 130 is embedded in the insulating layer 120, in accordance with some embodiments. The top surface 130a of the conductive pillar 130 is exposed by the insulating layer 120, in accordance with some embodiments.

The insulating layer 120 includes layers 122 and 124, in accordance with some embodiments. The conductive pillar 130 includes a seed layer 132 and a conductive layer 134, in accordance with some embodiments. The layer 122 is formed over the substrate 110, in accordance with some embodiments. The layer 122 has an opening 122a, in accordance with some embodiments. The opening 122a exposes the top surface 116a of the bonding pad 116, in accordance with some embodiments.

The seed layer 132 is formed over the layer 122 and the top surface 116a of the bonding pad 116, in accordance with some embodiments. The conductive layer 134 is formed over the seed layer 132, in accordance with some embodiments. The layer 124 is formed over the layer 122 and surrounds the conductive pillar 130, in accordance with some embodiments.

The insulating layer 120 is made of a dielectric material such as a polymer material (e.g., polyimide or the like), in accordance with some embodiments. The seed layer 132 is made of a conductive material such as metal or alloys (e.g., TiCu), in accordance with some embodiments. The conductive layer 134 is made of a conductive material, such as metal (e.g., copper, aluminum, gold, silver, or tungsten) or alloys thereof, in accordance with some embodiments.

The molding layer 140 surrounds the substrate 110, the insulating layer 120, and the conductive pillar 130, in accordance with some embodiments. In some embodiments, the top surfaces 142, 120a, and 130a of the molding layer 140, the insulating layer 120, and the conductive pillar 130 are substantially level with each other.

The formation of the molding layer 140 includes forming a molding material layer (not shown) over and surrounding the substrate 110, the insulating layer 120, and the conductive pillar 130; removing the molding material layer over the insulating layer 120 and the conductive pillar 130 using a grinding process; and performing a cleaning process on the conductive pillar 130 to remove oxides from the top surface 130a of the conductive pillar 130, in accordance with some embodiments.

As shown in FIG. 1A, an insulating material layer 150a is formed over the insulating layer 120, the conductive pillar 130, and the molding layer 140, in accordance with some embodiments. The insulating material layer 150a is made of a photoresist material such as a negative photoresist material, in accordance with some embodiments.

The insulating material layer 150a is formed using a coating process, in accordance with some embodiments. Thereafter, a soft bake process is performed on the insulating material layer 150a, in accordance with some embodiments. The process temperature of the soft bake process ranges from about 110 degree C. to about 120 degree C., in accordance with some embodiments. The process time of the soft bake process ranges from about 2 minutes to about 5 minutes, in accordance with some embodiments.

Since the process temperature of the soft bake process is high, the upper part 150al and the lower part 150a2 of the insulating material layer 150a harden at different speeds, which results in the upper part 150al and the lower part 150a2 having different material properties, in accordance with some embodiments.

For example, the insulating material layer 150a is made of a negative photoresist material, and the upper part 150al has a lower photoresist sensitizer concentration than the lower part 150a2 after the soft bake process is performed, in accordance with some embodiments.

As shown in FIGS. 1A and 1B, the insulating material layer 150a over the conductive pillar 130 is partially removed to form a hole 152, in accordance with some embodiments. The remaining insulating material layer 150a forms an insulating material layer 150, in accordance with some embodiments. The hole 152 exposes the top surface 130a of the conductive pillar 130, in accordance with some embodiments.

The hole 152 has an inner wall 152s, in accordance with some embodiments. The inner wall 152s has a lower portion 152a and an upper portion 152b, in accordance with some embodiments. The lower portion 152a is between the upper portion 152b and the conductive pillar 130, in accordance with some embodiments.

The lower portion 152a is steeper than the upper portion 152b, in accordance with some embodiments. The lower portion 152a of the inner wall 152s is substantially perpendicular to a top surface 130a of the conductive pillar 130, in accordance with some embodiments.

The angle θ1 between the lower portion 152a of the inner wall 152s and the top surface 130a of the conductive pillar 130 ranges from about 88 degrees to 92 degrees, in accordance with some embodiments. The angle θ1 is about 90 degrees, in accordance with some embodiments.

The angle θ2 between the lower portion 152a and the upper portion 152b of the inner wall 152s ranges from about 120 degrees to 170 degrees, in accordance with some embodiments. The removal process includes a photolithography process, in accordance with some embodiments.

Since the upper part 150al has a lower photoresist sensitizer concentration than the lower part 150a2 of the insulating material layer 150a, the upper part 150al is removed easier than the lower part 150a2 in the photolithography process, in accordance with some embodiments. Therefore, the upper portion 152u of the hole 152 in the upper part 150al is wider than the lower portion 1521 of the hole 152 in the lower part 150a2, in accordance with some embodiments.

The (wider) upper portion 152u may facilitate the formation of a seed layer in the hole 152 and over the top surface 130a of the conductive pillar 130 using a sputtering process, in accordance with some embodiments.

Afterwards, a curing process is performed on the insulating material layer 150, in accordance with some embodiments. The process temperature of the curing process ranges from about 210 degree C. to about 250 degree C., in accordance with some embodiments.

Thereafter, a descum process is performed to remove residues from the conductive pillar 130, in accordance with some embodiments. The descum process includes an etching process such as a plasma etching process, in accordance with some embodiments.

FIG. 1C-1 is a top view of the semiconductor device structure of FIG. 1C, in accordance with some embodiments. FIG. 1C is a cross-sectional view illustrating the semiconductor device structure along a sectional line I-I′ in FIG. 1C-1, in accordance with some embodiments. As shown in FIGS. 1C and 1C-1, a conductive structure 160 is formed in the hole 152 and over the insulating layer 150, in accordance with some embodiments. For the sake of simplicity, FIG. 1C-1 only shows the conductive pillar 130 and the conductive structure 160, in accordance with some embodiments.

The conductive structure 160 includes a conductive via structure 160a and a conductive line 160b, in accordance with some embodiments. The conductive via structure 160a is formed in the hole 152, in accordance with some embodiments. The conductive via structure 160a passes through the insulating layer 150 and is connected to the conductive pillar 130, in accordance with some embodiments. The conductive line 160b is formed over the conductive via structure 160a and the insulating layer 150, in accordance with some embodiments.

The conductive via structure 160a has a sidewall S, in accordance with some embodiments. The sidewall S has a lower portion S1 and a upper portion S2, in accordance with some embodiments. The lower portion S1 is between the upper portion S2 and the conductive pillar 130, in accordance with some embodiments.

The lower portion S2 is steeper than the upper portion S1, in accordance with some embodiments. The lower portion S2 is substantially perpendicular to the top surface 130a of the conductive pillar 130, in accordance with some embodiments.

The angle θ1′ between the lower portion S1 and the top surface 130a of the conductive pillar 130 ranges from about 88 degrees to 92 degrees, in accordance with some embodiments. The angle θ1′ is about 90 degrees, in accordance with some embodiments. The angle θ2′ between the lower portion S1 and the upper portion S2 ranges from about 120 degrees to 170 degrees, in accordance with some embodiments.

According to the simulation results, if the angle θ1′ is approximately 90 degrees, cracks caused by the difference in thermal expansion coefficients of the conductive via structure 160a and the insulating layer 150 can be prevented, in accordance with some embodiments.

The conductive structure 160 includes a seed layer 162 and a conductive layer 164, in accordance with some embodiments. The seed layer 162 is formed over the insulating layer 150 and the top surface 130a of the conductive pillar 130, in accordance with some embodiments. The conductive layer 164 is formed over the seed layer 162, in accordance with some embodiments.

The seed layer 162 is made of a conductive material such as metal or alloys (e.g., TiCu), in accordance with some embodiments. The conductive layer 164 is made of a conductive material, such as metal (e.g., copper, aluminum, gold, silver, or tungsten) or alloys thereof, in accordance with some embodiments.

As shown in FIG. 1D, an insulating layer 170 is formed over the insulating layer 150 and the conductive line 160b, in accordance with some embodiments. The insulating layer 170 has a hole 172 exposing the conductive line 160b, in accordance with some embodiments. The insulating layer 170 is made of a polymer material such as a photoresist material (e.g., a negative photoresist material), polyimide, or the like, in accordance with some embodiments.

FIG. 1D-1 is a top view of the semiconductor device structure of FIG. 1D, in accordance with some embodiments. FIG. 1D is a cross-sectional view illustrating the semiconductor device structure along a sectional line I-I′ in FIG. 1D-1, in accordance with some embodiments. As shown in FIGS. 1D and 1D-1, a conductive structure 180 is formed in the hole 172 and over the insulating layer 170, in accordance with some embodiments.

The conductive structure 180 includes a conductive via structure 180a and a conductive line 180b, in accordance with some embodiments. For the sake of simplicity, FIG. 1D-1 only shows the conductive pillar 130, the conductive structure 160, and the conductive via structure 180a, in accordance with some embodiments.

The conductive via structure 180a is formed in the hole 172, in accordance with some embodiments. The conductive via structure 180a passes through the insulating layer 170 and is connected to the conductive line 160b, in accordance with some embodiments. The conductive line 180b is formed over the conductive via structure 180a and the insulating layer 170, in accordance with some embodiments.

The conductive structure 180 includes a seed layer 182 and a conductive layer 184, in accordance with some embodiments. The seed layer 182 is formed over the insulating layer 170 and the top surface 160b1 of the conductive line 160b, in accordance with some embodiments. The conductive layer 184 is formed over the seed layer 182, in accordance with some embodiments.

The seed layer 182 is made of a conductive material such as metal or alloys (e.g., TiCu), in accordance with some embodiments. The conductive layer 184 is made of a conductive material, such as metal (e.g., copper, aluminum, gold, silver, or tungsten) or alloys thereof, in accordance with some embodiments.

As shown in FIG. 1D, an insulating layer 190 is formed over the insulating layer 170 and the conductive line 180b, in accordance with some embodiments. The insulating layer 190 has a hole 192 exposing the conductive line 180b, in accordance with some embodiments. The insulating layer 190 is made of a polymer material such as a photoresist material (e.g., a negative photoresist material), polyimide, or the like, in accordance with some embodiments.

As shown in FIGS. 1D and 1D-1, a conductive structure 210 is formed in the hole 192 and over the insulating layer 190, in accordance with some embodiments. The conductive structure 210 includes a conductive via structure 210a and a conductive line 210b, in accordance with some embodiments. The conductive via structure 210a is formed in the hole 192, in accordance with some embodiments.

The conductive via structure 210a passes through the insulating layer 190 and is connected to the conductive line 180b, in accordance with some embodiments. The conductive line 210b is formed over the conductive via structure 210a and the insulating layer 190, in accordance with some embodiments. The insulating layers 150, 170 and 190, the conductive via structures 160a, 180a, and 210a, and the conductive lines 160b, 180b, and 210b together form a redistribution structure 10, in accordance with some embodiments.

The conductive structure 210 includes a seed layer 212 and a conductive layer 214, in accordance with some embodiments. The seed layer 212 is formed over the insulating layer 190 and the top surface 180b1 of the conductive line 180b, in accordance with some embodiments. The conductive layer 214 is formed over the seed layer 212, in accordance with some embodiments.

The average width of the conductive via structure 160a is less than or equal to the average width of the conductive via structure 180a, in accordance with some embodiments. The average width of the conductive via structure 180a is less than or equal to the average width of the conductive via structure 210a, in accordance with some embodiments.

The seed layer 212 is made of a conductive material such as metal or alloys (e.g., TiCu), in accordance with some embodiments. The conductive layer 214 is made of a conductive material, such as metal (e.g., copper, aluminum, gold, silver, or tungsten) or alloys thereof, in accordance with some embodiments. In this step, a semiconductor device structure 100 is substantially formed, in accordance with some embodiments.

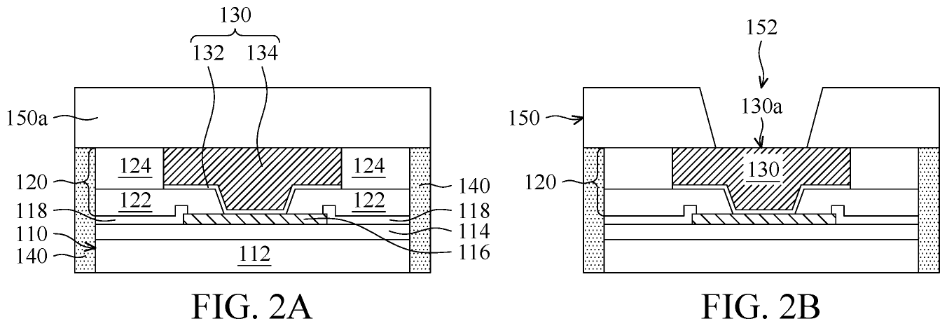

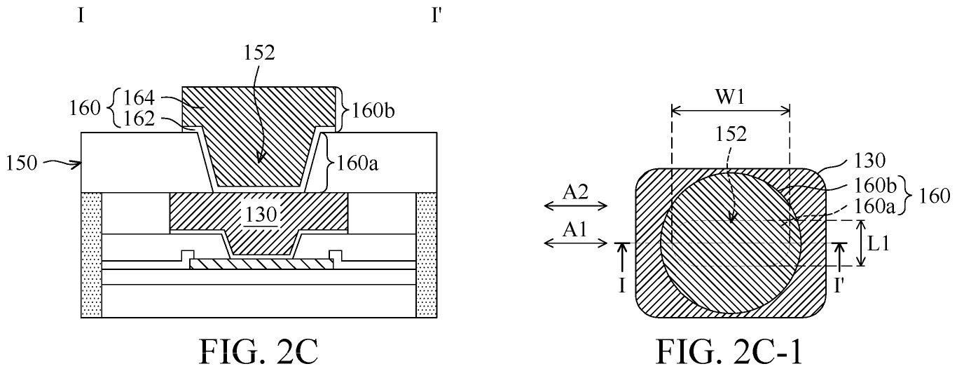

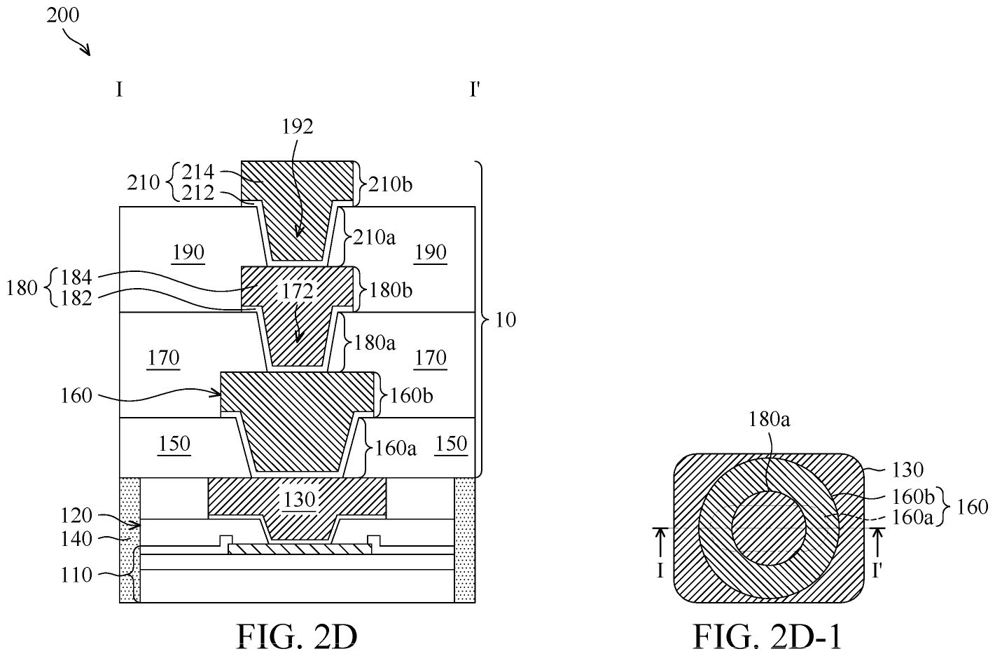

FIGS. 2A-2D are cross-sectional views of various stages of a process for is formed a semiconductor device structure, in accordance with some embodiments. As shown in FIG. 2A, the step of FIG. 1A is performed to form the substrate 110, the insulating layer 120, the conductive pillar 130, the molding layer 140, and the insulating material layer 150a, in accordance with some embodiments.

As shown in FIG. 2B, the insulating material layer 150a over the conductive pillar 130 is partially removed to form a hole 152, in accordance with some embodiments. The remaining insulating material layer 150a forms an insulating layer 150, in accordance with some embodiments. The hole 152 exposes the top surface 130a of the conductive pillar 130, in accordance with some embodiments.

FIG. 2C-1 is a top view of the semiconductor device structure of FIG. 2C, in accordance with some embodiments. FIG. 2C is a cross-sectional view illustrating the semiconductor device structure along a sectional line I-I′ in FIG. 2C-1, in accordance with some embodiments.

As shown in FIGS. 2C and 2C-1, the step of FIG. 1C is performed to form the conductive structure 160, in accordance with some embodiments. For the sake of simplicity, FIG. 2C-1 only shows the conductive pillar 130 and the conductive structure 160, in accordance with some embodiments.

As shown in FIGS. 1C-1 and 2C-1, the shapes of the conductive pillar 130 and the conductive via structure 160a of FIG. 2C-1 are different from that of FIG. 1C-1. The conductive pillar 130 of FIG. 2C-1 has a strip shape (or an oval shape), in accordance with some embodiments.

The conductive via structure 160a of FIG. 2C-1 has a strip shape (or an oval shape), in accordance with some embodiments. As shown in FIG. 2C-1, a long axis A1 of the conductive via structure 160a is substantially parallel to a long axis A2 of the conductive pillar 130, in accordance with some embodiments.

In some embodiments, a difference between the width W1 and the length L1 of the conductive via structure 160a ranges from about 0.6 μm to about 5 μm. In some embodiments, a ratio of the width W1 to the length L1 ranges from about 1 to about 5.

Since the conductive pillar 130 and the conductive via structure 160a both have a strip shape, the contact area between the conductive pillar 130 and the conductive via structure 160a is increased, which prevents the cracks between the conductive pillar 130 and the conductive via structure 160a, in accordance with some embodiments.

Since the conductive pillar 130 has a strip shape, the contact area between the conductive pillar 130 and the insulating layer 150 is increased, which prevents the cracks between the conductive pillar 130 and the insulating layer 150, in accordance with some embodiments. Therefore, the reliability of the semiconductor device structure with the conductive pillar 130 and the conductive via structure 160a is improved, in accordance with some embodiments.

FIG. 2D-1 is a top view of the semiconductor device structure of FIG. 2D, in accordance with some embodiments. FIG. 2D is a cross-sectional view illustrating the semiconductor device structure along a sectional line I-I′ in FIG. 2D-1, in accordance with some embodiments. As shown in FIGS. 2D and 2D-1, the step of FIG. 1D is performed to form the insulating layer 170, the conductive via structure 180a, the conductive line 180b, the insulating layer 190, the conductive via structure 210a, and the conductive line 210b, in accordance with some embodiments.

For the sake of simplicity, FIG. 2D-1 only shows the conductive pillar 130, the conductive structure 160, and the conductive via structure 180a, in accordance with some embodiments. The insulating layers 150, 170 and 190, the conductive via structures 160a, 180a, and 210a, and the conductive lines 160b, 180b, and 210b together form a redistribution structure 10, in accordance with some embodiments. In this step, a semiconductor device structure 200 is substantially formed, in accordance with some embodiments.

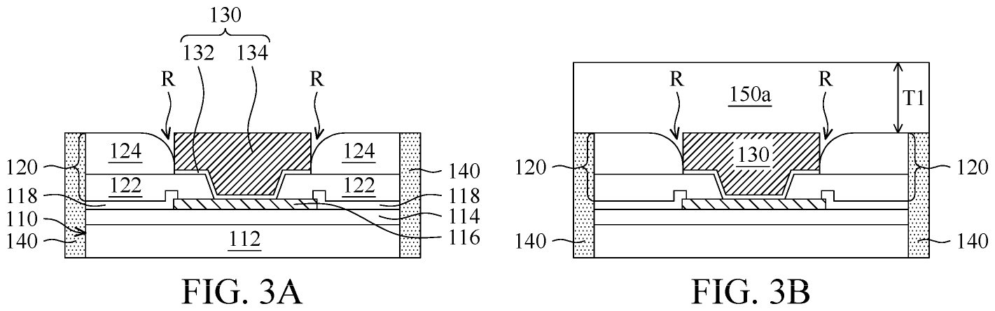

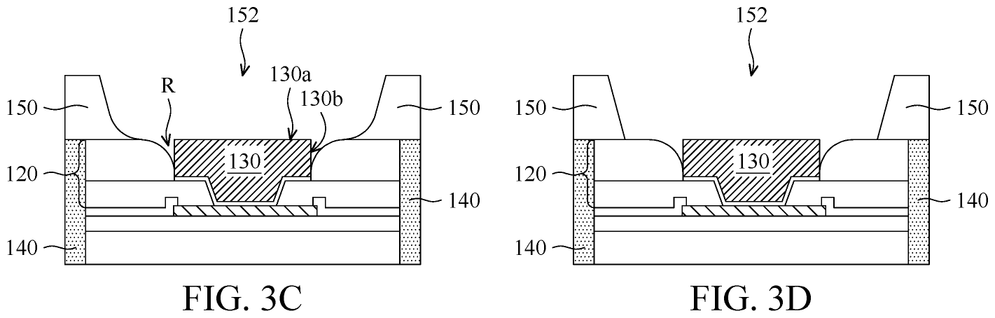

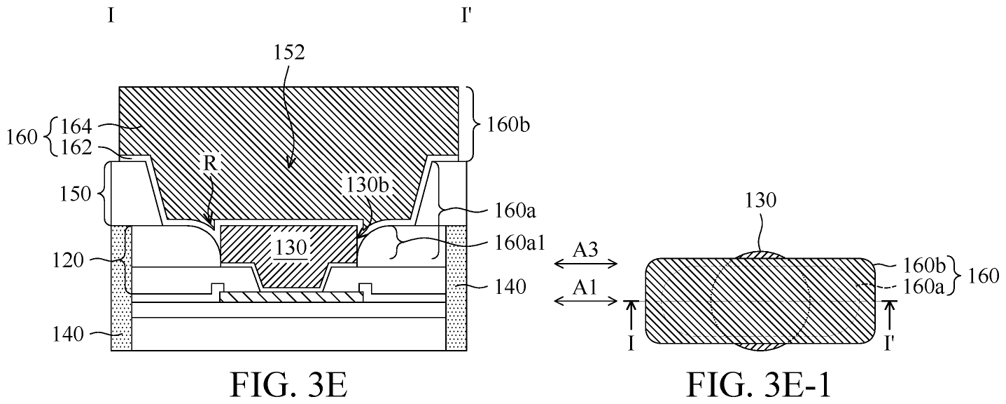

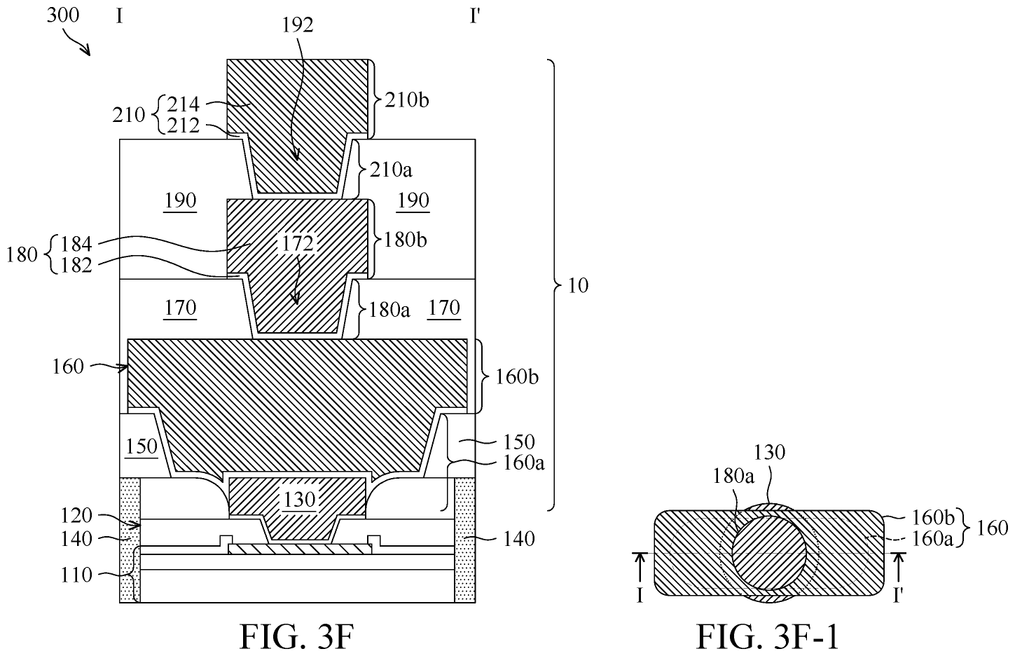

FIGS. 3A-3F are cross-sectional views of various stages of a process for is formed a semiconductor device structure, in accordance with some embodiments. As shown in FIG. 3A, the step of FIG. 1A is performed to form the substrate 110, the insulating layer 120, the conductive pillar 130, and the molding layer 140, in accordance with some embodiments. There is a recess R between the layer 124 of the insulating layer 120 and the conductive pillar 130, in accordance with some embodiments.

As shown in FIG. 3B, an insulating material layer 150a is formed over the insulating layer 120 and the conductive pillar 130 and in the recess R, in accordance with some embodiments. Thereafter, a soft bake process is performed on the insulating material layer 150a, in accordance with some embodiments. The process temperature of the soft bake process ranges from about 100 degree C. to about 120 degree C., in accordance with some embodiments.

As shown in FIG. 3C, the insulating material layer 150a over the conductive pillar 130 is partially removed to form a hole 152, in accordance with some embodiments. The remaining insulating material layer 150a forms an insulating material layer 150, in accordance with some embodiments.

The hole 152 is wider than the conductive pillar 130, in accordance with some embodiments. The hole 152 exposes the top surface 130a and sidewalls 130b of the conductive pillar 130 and a portion of the insulating layer 120, in accordance with some embodiments.

Afterwards, as shown in FIG. 3D, a curing process is performed on the insulating layer 150, in accordance with some embodiments. The process temperature of the curing process ranges from about 210 degree C. to about 250 degree C., in accordance with some embodiments.

Thereafter, as shown in FIG. 3D, a descum process is performed to remove residues from the conductive pillar 130, in accordance with some embodiments. The descum process includes an etching process such as a plasma etching process, in accordance with some embodiments. The descum process may remove portions of the insulating layers 120 and 150, in accordance with some embodiments.

FIG. 3E-1 is a top view of the semiconductor device structure of FIG. 3E, in accordance with some embodiments. FIG. 3E is a cross-sectional view illustrating the semiconductor device structure along a sectional line I-I′ in FIG. 3E-1, in accordance with some embodiments.

As shown in FIGS. 3E and 3E-1, the step of FIG. 1C is performed to form the conductive structure 160, in accordance with some embodiments. For the sake of simplicity, FIG. 3E-1 only shows the conductive pillar 130 and the conductive structure 160, in accordance with some embodiments.

As shown in FIGS. 1C-1 and 3E-1, the shapes of the conductive via structure 160a and the conductive line 160b of FIG. 3E-1 are different from that of FIG. 1C-1, in accordance with some embodiments. The conductive line 160b of FIG. 3E-1 has a strip shape (or an oval shape), in accordance with some embodiments. The conductive via structure 160a of FIG. 3E-1 has a strip shape (or an oval shape), in accordance with some embodiments.

As shown in FIG. 3E-1, the long axis A1 of the conductive via structure 160a is substantially parallel to a long axis A3 of the conductive line 160b, in accordance with some embodiments. The conductive via structure 160a is wider than the conductive pillar 130, in accordance with some embodiments. The conductive line 160b is wider than the conductive pillar 130, in accordance with some embodiments.

Since the conductive via structure 160a and the conductive line 160b both have a strip shape, the contact area between the conductive via structure 160a and the conductive line 160b is increased, which prevents the cracks between the conductive via structure 160a and the conductive line 160b, in accordance with some embodiments. Therefore, the reliability of the semiconductor device structure with the conductive via structure 160a and the conductive line 160b is improved, in accordance with some embodiments.

In some embodiments, a bottom portion 160al of the conductive via structure 160a is embedded in the insulating layer 120. The bottom portion 160al of the conductive via structure 160a is in direct contact with the sidewall 130b of the conductive pillar 130, in accordance with some embodiments.

The conductive pillar 130 extends into the conductive via structure 160a, which increases the contact area between the conductive pillar 130 and the conductive via structure 160a, which prevents the cracks between the conductive pillar 130 and the conductive via structure 160a, in accordance with some embodiments. Therefore, the reliability of the semiconductor device structure with the conductive via structure 160a is improved, in accordance with some embodiments.

FIG. 3F-1 is a top view of the semiconductor device structure of FIG. 3F, in accordance with some embodiments. FIG. 3F is a cross-sectional view illustrating the semiconductor device structure along a sectional line I-I′ in FIG. 3F-1, in accordance with some embodiments.

As shown in FIGS. 3F and 3F-1, the step of FIG. 1D is performed to form the insulating layer 170, the conductive via structure 180a, the conductive line 180b, the insulating layer 190, the conductive via structure 210a, and the conductive line 210b, in accordance with some embodiments.

For the sake of simplicity, FIG. 3F-1 only shows the conductive pillar 130, the conductive structure 160, and the conductive via structure 180a, in accordance with some embodiments. The insulating layers 150, 170 and 190, the conductive via structures 160a, 180a, and 210a, and the conductive lines 160b, 180b, and 210b together form a redistribution structure 10, in accordance with some embodiments. In this step, a semiconductor device structure 300 is substantially formed, in accordance with some embodiments.

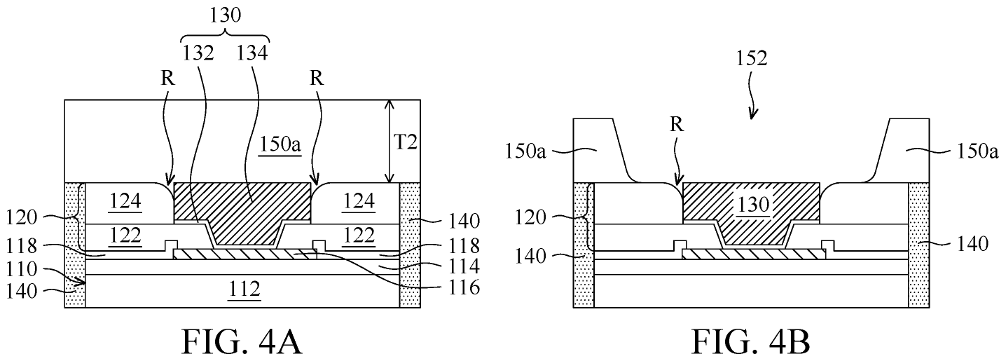

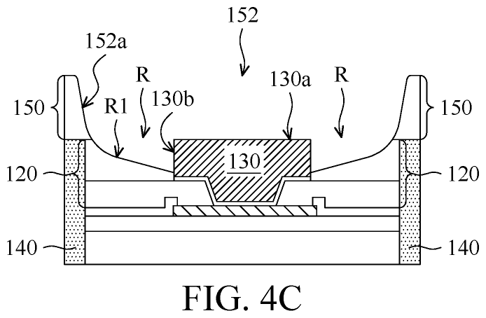

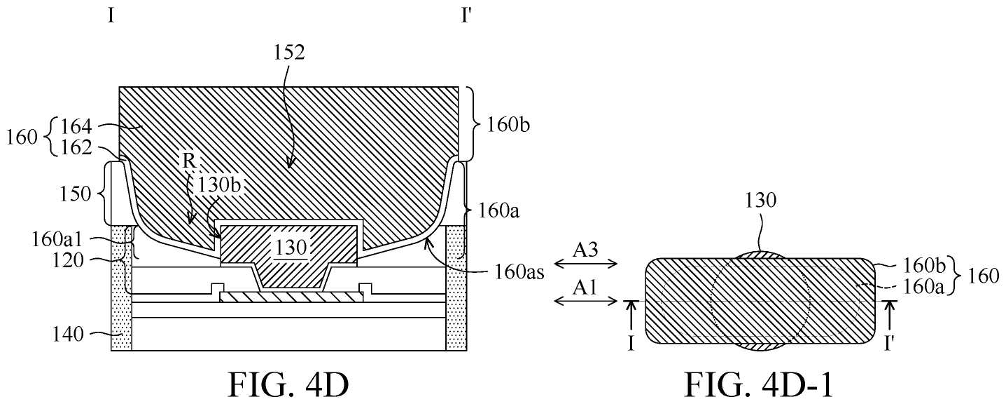

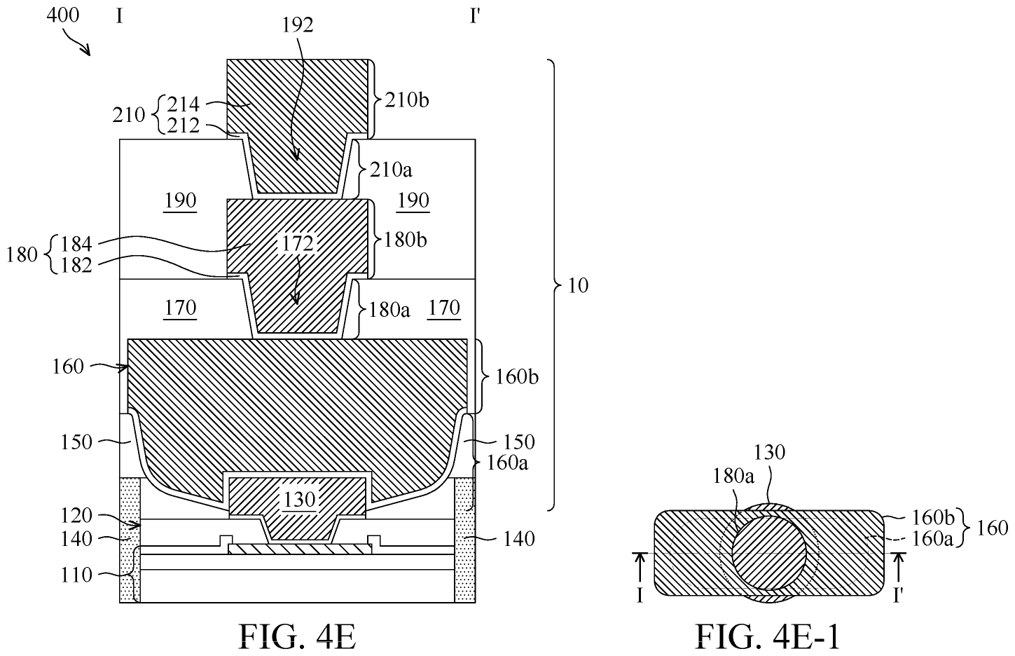

FIGS. 4A-4E are cross-sectional views of various stages of a process for is formed a semiconductor device structure, in accordance with some embodiments. As shown in FIG. 4A, the steps of FIGS. 3A and 3B are performed to form the substrate 110, the insulating layer 120, the conductive pillar 130, the molding layer 140, and the insulating material layer 150a, in accordance with some embodiments. The thickness T2 of the insulating material layer 150a of FIG. 4A is greater than the thickness T1 of the insulating material layer 150a of FIG. 3B, in accordance with some embodiments.

As shown in FIG. 4B, the insulating material layer 150a over the conductive pillar 130 is partially removed to form the hole 152, in accordance with some embodiments.

As shown in FIGS. 4B and 4C, a curing process is performed on the insulating material layer 150a, in accordance with some embodiments.

Thereafter, as shown in FIG. 4C, a descum process is performed to remove residues from the conductive pillar 130, in accordance with some embodiments. The descum process also removes portions of the insulating layers 120 and 150 to widen the hole 152 and the recess R, in accordance with some embodiments. The remaining insulating material layer 150a forms the insulating layer 150 after the descum process, in accordance with some embodiments. The insulating layer 150 is thinned after the descum process, in accordance with some embodiments.

The descum process includes an isotropic etching process, in accordance with some embodiments. The roughness of the inner wall 152a of the hole 152 is greater than the roughness of the top surface 130a of the conductive pillar 130 after the isotropic etching process is performed, in accordance with some embodiments.

The roughness of the inner walls R1 of the recess R is greater than the roughness of the top surface 130a of the conductive pillar 130 after the isotropic etching process is performed, in accordance with some embodiments. The inner walls R1 are curved inner walls, in accordance with some embodiments.

FIG. 4D-1 is a top view of the semiconductor device structure of FIG. 4D, in accordance with some embodiments. FIG. 4D is a cross-sectional view illustrating the semiconductor device structure along a sectional line I-I′ in FIG. 4D-1, in accordance with some embodiments.

As shown in FIGS. 4D and 4D-1, the step of FIG. 1C is performed to form the conductive structure 160, in accordance with some embodiments. For the sake of simplicity, FIG. 4D-1 only shows the conductive pillar 130 and the conductive structure 160, in accordance with some embodiments.

As shown in FIGS. 1C-1 and 4D-1, the shapes of the conductive via structure 160a and the conductive line 160b of FIG. 4D-1 are different from that of FIG. 1C-1, in accordance with some embodiments. The conductive line 160b of FIG. 4D-1 has a strip shape (or an oval shape), in accordance with some embodiments. The conductive via structure 160a of FIG. 4D-1 has a strip shape (or an oval shape), in accordance with some embodiments.

As shown in FIG. 4D-1, the long axis A1 of the conductive via structure 160a is substantially parallel to a long axis A3 of the conductive line 160b, in accordance with some embodiments. The conductive via structure 160a is wider than the conductive pillar 130, in accordance with some embodiments. The conductive line 160b is wider than the conductive pillar 130, in accordance with some embodiments.

In some embodiments, a bottom portion 160al of the conductive via structure 160a is embedded in the insulating layer 120. The bottom portion 160al of the conductive via structure 160a is in direct contact with the sidewall 130b of the conductive pillar 130, in accordance with some embodiments.

The conductive pillar 130 extends into the conductive via structure 160a, in accordance with some embodiments. As shown in FIG. 4D, the conductive via structure 160a has a curved sidewall 160as, in accordance with some embodiments.

FIG. 4E-1 is a top view of the semiconductor device structure of FIG. 4E, in accordance with some embodiments. FIG. 4E is a cross-sectional view illustrating the semiconductor device structure along a sectional line I-I′ in FIG. 4E-1, in accordance with some embodiments.

As shown in FIGS. 4E and 4E-1, the step of FIG. 1D is performed to form the insulating layer 170, the conductive via structure 180a, the conductive line 180b, the insulating layer 190, the conductive via structure 210a, and the conductive line 210b, in accordance with some embodiments. For the sake of simplicity, FIG. 4E-1 only shows the conductive pillar 130, the conductive structure 160, and the conductive via structure 180a, in accordance with some embodiments.

The insulating layers 150, 170 and 190, the conductive via structures 160a, 180a, and 210a, and the conductive lines 160b, 180b, and 210b together form a redistribution structure 10, in accordance with some embodiments. In this step, a semiconductor device structure 400 is substantially formed, in accordance with some embodiments.

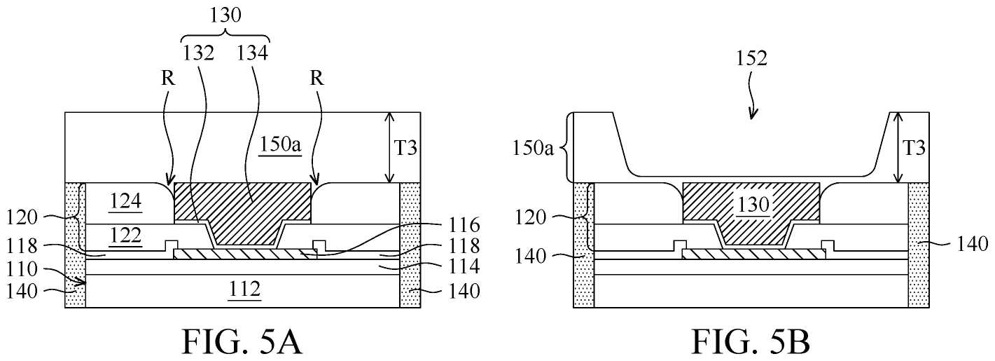

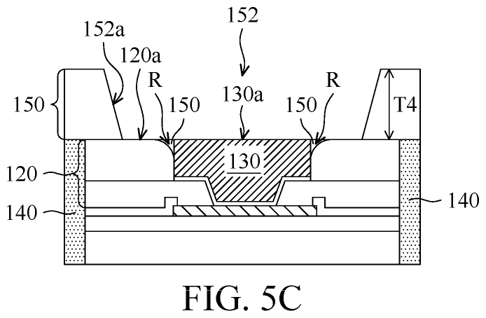

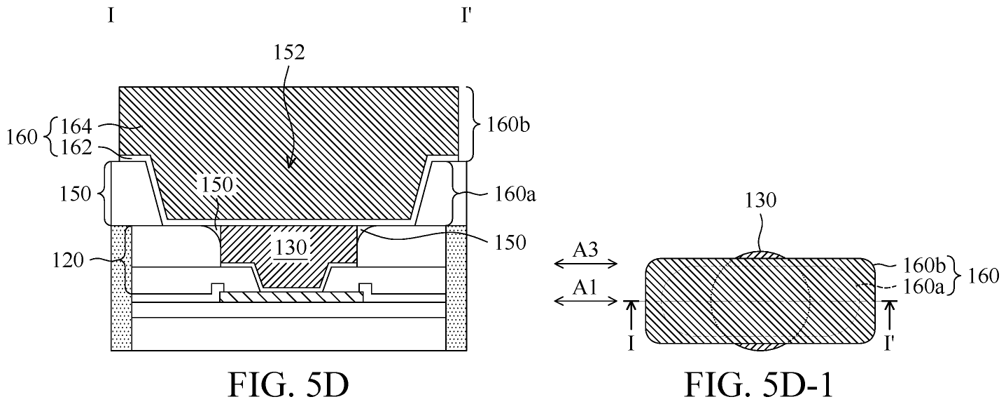

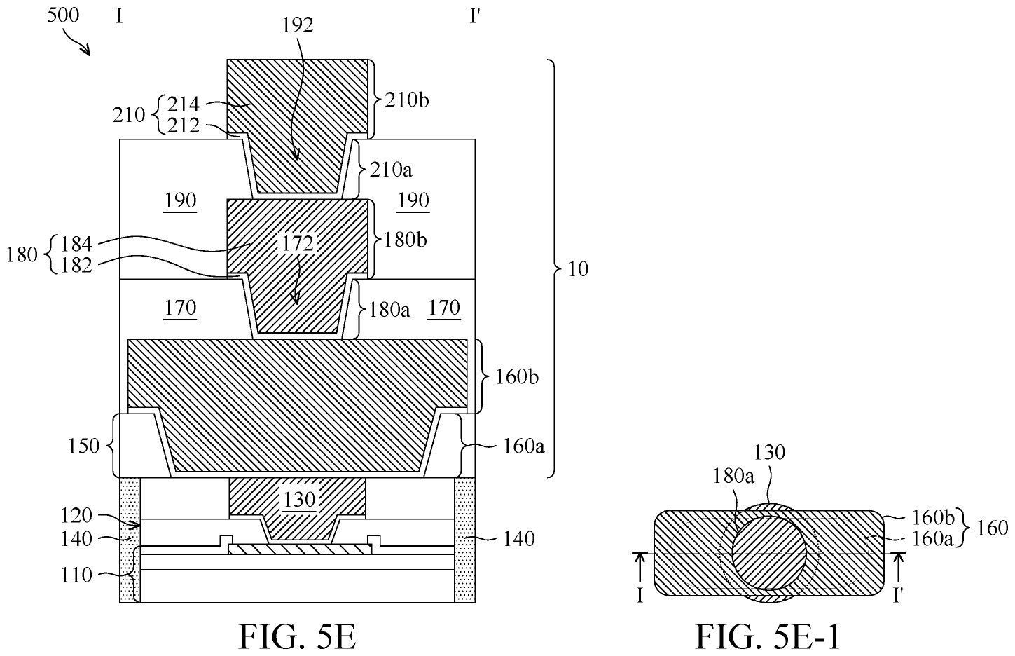

FIGS. 5A-5E are cross-sectional views of various stages of a process for is formed a semiconductor device structure, in accordance with some embodiments. As shown in FIG. 5A, the steps of FIGS. 3A and 3B are performed to form the substrate 110, the insulating layer 120, the conductive pillar 130, the molding layer 140, and the insulating material layer 150a, in accordance with some embodiments. The thickness T3 of the insulating material layer 150a of FIG. 5A is greater than the thickness T1 of the insulating material layer 150a of FIG. 3B, in accordance with some embodiments.

After the soft bake process is performed, an annealing process is performed on the insulating material layer 150a to improve the adhesion between the insulating material layer 150a and the conductive pillar 130, in accordance with some embodiments. The annealing temperature is higher than the soft bake temperature, in accordance with some embodiments. The annealing temperature ranges from about 130 degree C. to about 150 degree C., in accordance with some embodiments.

As shown in FIG. 5B, the insulating material layer 150a over the conductive pillar 130 is partially removed to form the hole 152, in accordance with some embodiments.

Since the annealing process improves the adhesion between the insulating material layer 150a and the conductive pillar 130, a portion of the insulating material layer 150a remains over the insulating layer 120 and the conductive pillar 130.

As shown in FIG. 5C, a curing process is performed on the insulating material layer 150a, in accordance with some embodiments. Thereafter, as shown in FIG. 5C, the portions of the insulating material layer 150a remaining over the insulating layer 120 and the conductive pillar 130 are removed, in accordance with some embodiments. The remaining insulating material layer 150a forms the insulating layer 150 after the descum process, in accordance with some embodiments.

In some embodiments, portions of the insulating layer 150 remain in the recess R between the insulating layer 120 and the conductive pillar 130. The removal process includes a descum process, in accordance with some embodiments. The insulating layer 150 is thinned after the descum process, in accordance with some embodiments. That is, the thickness T4 of the insulating layer 150 is less than the thickness T3 of the insulating material layer 150a of FIG. 5A or 5B, in accordance with some embodiments.

The descum process includes an isotropic etching process, in accordance with some embodiments. The roughness of the inner wall 152a of the hole 152 is greater than the roughness of the top surface 130a of the conductive pillar 130 after the isotropic etching process is performed, in accordance with some embodiments.

The roughness of the top surface 120a of the insulating layer 120 is greater than the roughness of the top surface 130a of the conductive pillar 130 after the isotropic etching process is performed, in accordance with some embodiments.

FIG. 5D-1 is a top view of the semiconductor device structure of FIG. 5D, in accordance with some embodiments. FIG. 5D is a cross-sectional view illustrating the semiconductor device structure along a sectional line I-I′ in FIG. 5D-1, in accordance with some embodiments.

As shown in FIGS. 5D and 5D-1, the step of FIG. 1C is performed to form the conductive structure 160, in accordance with some embodiments. For the sake of simplicity, FIG. 5D-1 only shows the conductive pillar 130 and the conductive structure 160, in accordance with some embodiments.

As shown in FIGS. 1C-1 and 5D-1, the shapes of the conductive via structure 160a and the conductive line 160b of FIG. 5D-1 are different from that of FIG. 1C-1, in accordance with some embodiments. The conductive line 160b of FIG. 5D-1 has a strip shape (or an oval shape), in accordance with some embodiments. The conductive via structure 160a of FIG. 5D-1 has a strip shape (or an oval shape), in accordance with some embodiments.

As shown in FIG. 5D-1, the long axis A1 of the conductive via structure 160a is substantially parallel to a long axis A3 of the conductive line 160b, in accordance with some embodiments. The conductive via structure 160a is wider than the conductive pillar 130, in accordance with some embodiments. The conductive line 160b is wider than the conductive pillar 130, in accordance with some embodiments. As shown in FIG. 5D, the entire conductive via structure 160a is over the insulating layer 120, in accordance with some embodiments.

FIG. 5E-1 is a top view of the semiconductor device structure of FIG. 5E, in accordance with some embodiments. FIG. 5E is a cross-sectional view illustrating the semiconductor device structure along a sectional line I-I′ in FIG. 5E-1, in accordance with some embodiments.

As shown in FIGS. 5E and 5E-1, the step of FIG. 1D is performed to form the insulating layer 170, the conductive via structure 180a, the conductive line 180b, the insulating layer 190, the conductive via structure 210a, and the conductive line 210b, in accordance with some embodiments. For the sake of simplicity, FIG. 5E-1 only shows the conductive pillar 130, the conductive structure 160, and the conductive via structure 180a, in accordance with some embodiments.

The insulating layers 150, 170 and 190, the conductive via structures 160a, 180a, and 210a, and the conductive lines 160b, 180b, and 210b together form a redistribution structure 10, in accordance with some embodiments. In this step, a semiconductor device structure 500 is substantially formed, in accordance with some embodiments.

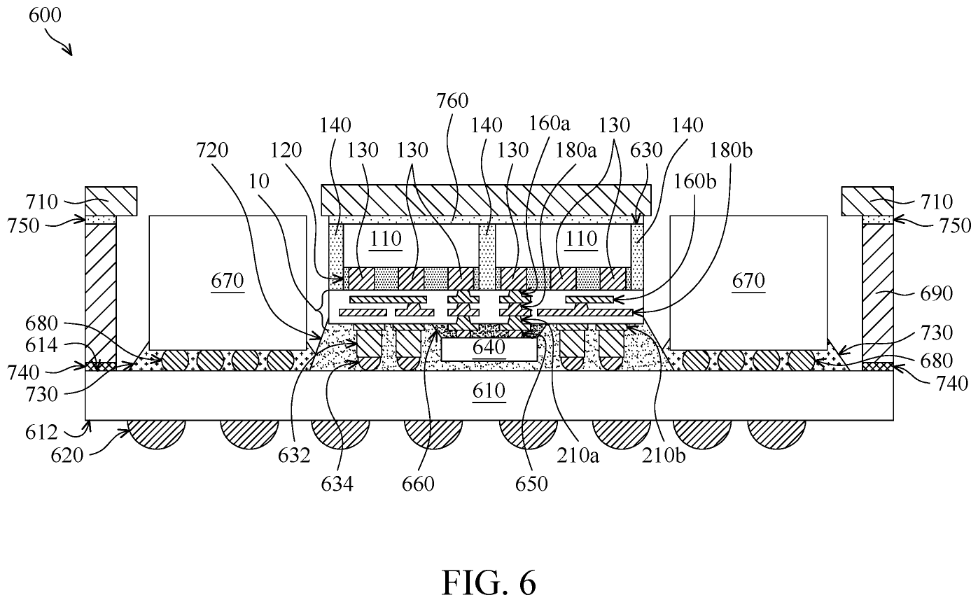

FIG. 6 is a cross-sectional view of a package structure 600, in accordance with some embodiments. As shown in FIG. 6, the package structure 600 includes a wiring substrate 610, solder balls 620, a package 630, a chip 640, solder balls 650, an underfill layer 660, chip-containing structures 670, solder balls 680, a ring structure 690, a lid 710, underfill layers 720 and 730, adhesive layers 740 and 750, and a heat conductive layer 760, in accordance with some embodiments.

The wiring substrate 610 includes an insulating layer (not shown) and a wiring structure (not shown) in the insulating layer, in accordance with some embodiments. The solder balls 620 are formed over a bottom surface 612 of the wiring substrate 610, in accordance with some embodiments. The solder balls 620 are electrically connected to the wiring structure of the wiring substrate 610, in accordance with some embodiments.

The package 630 is bonded to a top surface 614 of the wiring substrate 610, in accordance with some embodiments. The package 630 is electrically connected to the wiring structure of the wiring substrate 610, in accordance with some embodiments. The package 630 is similar to the semiconductor device structure 100, 200, 300, 400 or 500 of FIG. 1D, 2D, 3F, 4E, or 5E, except that the package 630 has two substrates 110, in accordance with some embodiments.

The package 630 includes the substrates 110, the insulating layer 120, the conductive pillar 130, the molding layer 140, and the redistribution structure 10 of the semiconductor device structure 100, 200, 300, 400 or 500, in accordance with some embodiments.

The package 630 further includes conductive pillars 632 and solder balls 634, in accordance with some embodiments. The conductive pillars 632 are formed over the redistribution structure 10, in accordance with some embodiments. The solder balls 634 are connected between the conductive pillars 632 and the wiring substrate 610, in accordance with some embodiments.

The chip 640 is bonded to the redistribution structure 10 through the solder balls 650, in accordance with some embodiments. The underfill layer 660 is formed between the redistribution structure 10 and the chip 640, in accordance with some embodiments.

The chip-containing structures 670 are bonded to the redistribution structure 10 through the solder balls 680, in accordance with some embodiments. The ring structure 690 is bonded to the redistribution structure 10 and surrounds the package 630 and the chip-containing structures 670, in accordance with some embodiments. The lid 710 is bonded to the ring 690, in accordance with some embodiments.

The solder balls 620, 634, 650, and 680 are made of metal or alloys thereof such as tin alloy, in accordance with some embodiments. The conductive pillars 632 are made of a conductive material, such as metal (e.g., copper, aluminum, gold, silver, or tungsten) or alloys thereof, in accordance with some embodiments.

The underfill layer 660 is made of an insulating material such as a polymer material, in accordance with some embodiments. The lid 710 and the ring 690 are made of metal or alloys, in accordance with some embodiments.

The underfill layer 720 is formed between the wiring substrate 610 and the package 630, in accordance with some embodiments. The underfill layer 720 surrounds the conductive line 210b, the conductive pillars 632, the solder balls 634, the chip 640, and the underfill layer 660, in accordance with some embodiments.

The underfill layer 730 is formed between the wiring substrate 610 and the corresponding chip-containing structure 670, in accordance with some embodiments. The underfill layer 730 surrounds the corresponding solder balls 680, in accordance with some embodiments. The underfill layers 720 and 730 are made of an insulating material such as a polymer material, in accordance with some embodiments.

The adhesive layer 740 is formed between the ring structure 690 and the wiring substrate 610, in accordance with some embodiments. The adhesive layer 750 is formed between the ring structure 690 and the lid 710, in accordance with some embodiments. The adhesive layers 740 and 750 are made of an adhesive material such as a polymer material, in accordance with some embodiments.

The heat conductive layer 760 is formed between the lid 710 and the package 630, in accordance with some embodiments. The heat conductive layer 760 is made of a heat conductive material such as indium (In), tin (Sn), or an appropriate material with a good thermal conductivity and thermal diffusivity, in accordance with some embodiments. The material of the heat conductive layer 760 has a thermal conductivity greater than or equal to 50 W/(m·K), in accordance with some embodiments.

The method for forming the package structure 600 includes: bonding the package 630 to the wiring substrate 610; forming the underfill layer 720 between the wiring substrate 610 and the package 630; bonding the chip-containing structures 670 to the wiring substrate 610; forming the underfill layers 730 between the wiring substrate 610 and the chip-containing structures 670; bonding the ring 690 to the wiring substrate 610 through the adhesive layer 740; bonding the lid 710 to the ring 690 and the package 630 through the adhesive layer 750 and the heat conductive layer 760; and forming the solder balls 620 over the bottom surface 612 of the wiring substrate 610, in accordance with some embodiments. These steps are performed sequentially, in accordance with some embodiments.

Processes and materials for forming the semiconductor device structures 200, 300, 400, and 500 may be similar to, or the same as, those for forming the semiconductor device structure 100 described above. Elements designated by the same or similar reference numbers as those in FIGS. 1A to 6 have the same or similar structures and the materials. Therefore, the detailed descriptions thereof will not be repeated herein.

In accordance with some embodiments, semiconductor device structures and methods for forming the same are provided. The methods (for forming the semiconductor device structure) form a conductive via structure with a strip shape to increase the contact area between the conductive via structure and a conductive pillar thereunder (or a conductive line thereover) to prevent the cracks between the conductive via structure and the conductive pillar thereunder (or the conductive line thereover).

In accordance with some embodiments, a method for forming a semiconductor device structure is provided. The method includes providing a substrate, a first insulating layer, and a conductive pillar over the substrate. The conductive pillar is embedded in the first insulating layer, and a top surface of the conductive pillar is exposed by the first insulating layer. The method includes forming a second insulating layer over the first insulating layer and the conductive pillar. The second insulating layer has a hole over the top surface of the conductive pillar. The method includes forming a conductive via structure in the hole and a conductive line over the conductive via structure and the second insulating layer. The conductive via structure has a first strip shape in a first top view of the conductive via structure.

In accordance with some embodiments, a method for forming a semiconductor device structure is provided. The method includes providing a substrate, a first insulating layer, and a conductive pillar over the substrate. The conductive pillar is embedded in the first insulating layer, and a top surface of the conductive pillar is exposed by the first insulating layer. The method includes forming a second insulating layer over the first insulating layer and the conductive pillar. The second insulating layer has a hole exposing the top surface of the conductive pillar, the hole has an inner wall, the inner wall has a upper portion and a lower portion, the lower portion is between the upper portion and the conductive pillar, and the lower portion is steeper than the upper portion. The method includes forming a conductive via structure in the hole and a conductive line over the conductive via structure and the second insulating layer.

In accordance with some embodiments, a semiconductor device structure is provided. The semiconductor device structure includes a substrate. The semiconductor device structure includes a first insulating layer over the substrate. The semiconductor device structure includes a conductive pillar over the substrate and embedded in the first insulating layer. The semiconductor device structure includes a second insulating layer over the first insulating layer and the conductive pillar. The semiconductor device structure includes a conductive via structure passing through the second insulating layer and connected to the conductive pillar. The conductive via structure has a first strip shape in a first top view of the conductive via structure. The semiconductor device structure includes a conductive line over the conductive via structure and the second insulating layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
providing a substrate, a first insulating layer, and a conductive pillar over the substrate, wherein the conductive pillar is embedded in the first insulating layer, and a top surface of the conductive pillar is exposed by the first insulating layer;
forming a second insulating layer over the first insulating layer and the conductive pillar, wherein the second insulating layer has a hole over the top surface of the conductive pillar; and
forming a conductive via structure in the hole and a conductive line over the conductive via structure and the second insulating layer, wherein the conductive via structure has a first strip shape in a first top view of the conductive via structure, a width of the conductive via structure is greater than a length of the conductive via structure, and the conductive line is in direct contact with the conductive via structure and wider than the conductive via structure.

2. The method for forming the semiconductor device structure as claimed in claim 1, wherein the conductive pillar has a second strip shape in a second top view of the conductive pillar.

3. The method for forming the semiconductor device structure as claimed in claim 2, wherein a first long axis of the conductive via structure is substantially parallel to a second long axis of the conductive pillar in a third top view of the conductive via structure and the conductive pillar.

4. The method for forming the semiconductor device structure as claimed in claim 1, wherein the conductive via structure is wider than the conductive pillar.

5. The method for forming the semiconductor device structure as claimed in claim 4, wherein the hole of the second insulating layer exposes a sidewall of the conductive pillar.

6. The method for forming the semiconductor device structure as claimed in claim 5, wherein a bottom portion of the conductive via structure is embedded in the first insulating layer.

7. The method for forming the semiconductor device structure as claimed in claim 6, wherein the bottom portion of the conductive via structure is in direct contact with the sidewall of the conductive pillar.

8. The method for forming the semiconductor device structure as claimed in claim 4, wherein the conductive via structure has a curved sidewall in a cross-sectional view of the conductive via structure.

9. The method for forming the semiconductor device structure as claimed in claim 8, wherein the forming of the second insulating layer over the first insulating layer and the conductive pillar comprises:
forming an insulating material layer over the first insulating layer and the conductive pillar;
partially removing the insulating material layer over the conductive pillar to form the hole;
performing a curing process on the insulating material layer; and
partially removing the insulating material layer to widen the hole, wherein the insulating material layer forms the second insulating layer after the hole is widened.

10. The method for forming the semiconductor device structure as claimed in claim 9, wherein the partially removing of the insulating material layer to widen the hole comprises:
performing an isotropic etching process on the insulating material layer.

11. The method for forming the semiconductor device structure as claimed in claim 10, wherein a first roughness of an inner wall of the hole is greater than a second roughness of a top surface of the conductive pillar after the isotropic etching process is performed.

12. The method for forming the semiconductor device structure as claimed in claim 10, wherein a first roughness of an upper surface of the first insulating layer is greater than a second roughness of a top surface of the conductive pillar after the isotropic etching process is performed.

13. The method for forming the semiconductor device structure as claimed in claim 1, wherein the conductive line has a second strip shape, and a first long axis of the conductive via structure is substantially parallel to a second long axis of the conductive line in a second top view of the conductive via structure and the conductive line.

14. A method for forming a semiconductor device structure, comprising:
providing a substrate, a first insulating layer, and a conductive pillar over the substrate, wherein the conductive pillar is embedded in the first insulating layer, and a top surface of the conductive pillar is exposed by the first insulating layer;
forming a second insulating layer over the first insulating layer and the conductive pillar, wherein the second insulating layer has a hole exposing the top surface of the conductive pillar, the hole has an inner wall, the inner wall has a upper portion and a lower portion, the lower portion is between the upper portion and the conductive pillar, and the lower portion is steeper than the upper portion; and
forming a conductive via structure in the hole and a conductive line over the conductive via structure and the second insulating layer.

15. The method for forming the semiconductor device structure as claimed in claim 14, wherein the lower portion of the inner wall is substantially perpendicular to a top surface of the conductive pillar.

16. A semiconductor device structure, comprising:
a substrate;
a first insulating layer over the substrate;
a conductive pillar over the substrate and embedded in the first insulating layer;
a second insulating layer over the first insulating layer and the conductive pillar;
a conductive via structure passing through the second insulating layer and connected to the conductive pillar, wherein the conductive via structure has a first strip shape in a first top view of the conductive via structure; and
a conductive line over the conductive via structure and the second insulating layer.

17. The semiconductor device structure as claimed in claim 16, wherein the conductive line has a second strip shape, and a first long axis of the conductive via structure is substantially parallel to a second long axis of the conductive line in a second top view of the conductive via structure and the conductive line.

18. The semiconductor device structure as claimed in claim 16, wherein the conductive pillar has a second strip shape in a second top view of the conductive pillar.

19. The semiconductor device structure as claimed in claim 16, wherein the conductive via structure is wider than the conductive pillar.

20. The semiconductor device structure as claimed in claim 19, wherein the conductive pillar extends into the conductive via structure.
